(19) United States
(12) Patent Application Publication
(10) Pub. No.: US 2025/0139325 A1
(43) Pub. Date: May 1, 2025

(54) SYSTEM AND METHOD FOR VERIFICATION OF WELL SERVICE DESIGN

(71) Applicant: Weatherford Technology Holdings, LLC, Houston, TX (US)

(72) Inventor: Leonardo Gutierrez, Houston, TX (US)

(21) Appl. No.: 18/503,492

(22) Filed: Nov. 7, 2023

Related U.S. Application Data
(60) Provisional application No. 63/594,477, filed on Oct. 31, 2023.

(51) Int. Cl. G06F 30/20; E21B 43/16

(52) U.S. Cl. CPC G06F 30/20; E21B 43/16

(57) ABSTRACT

Systems and methods monitor equipment used in performing well services. Machine-readable indicia (e.g., RFID tags) for the equipment are encoded with coded identifiers, each of which includes information about product line, operational classification, and unique identification. The encoded indicia are physically associated with the equipment, and tracking information is associated in the system with the coded identifiers. The system compiles a design list to implement a given service using equipment. The system then remotely tracks the equipment using the coded identifiers of the encoded indicia. In particular, the equipment in the design list is dispatched to the site by verifying the encoded indicia for the equipment, a dispatched list of the encoded indicia is received for the equipment obtained at the site, and the dispatched list is verified against the design list. Additional tracking of the equipment can be performed with the coded identifiers and encoded indica.

### CROSS-REFERENCE TO RELATED APPLICATIONS

This application claims the benefit of U.S. Provisional Appl. No. 63/120,092 filed Oct. 31, 2023, which is incorporated herein by reference in its entirety.

### BACKGROUND OF THE DISCLOSURE

When a well service job is requested, designed, executed, and finished, multiple pieces of well equipment need to be selected, organized, shipped, set up, run, and returned. In many well service operations, many different operational arms of a well service provider may be deployed to perform the well service job. As expected, the logistics involved in organizing and executing the well service job requires a great deal of time and requires repeated verification steps and checks along the way. Although there are many systems and methods known for managing assets and handling logistics, what is needed is a particular system and method for verifying the design and implementation of a well service by a well service provider for a client.

The subject matter of the present disclosure is directed to overcoming, or at least reducing the effects of, one or more of the problems set forth above.

### SUMMARY OF THE DISCLOSURE

Some implementations disclosed herein relate to a method implemented in a computerized client-server system of monitoring well service equipment used in performing well services at well sites. In one implementation, the method includes coding, in one or more databases of the computerized client-server system, (i) product line codes for each of a plurality of product lines covering the well service equipment, (ii) operational classification codes for each of a plurality of operations in each product line, and (iii) unique identification codes for each of a plurality of the well service equipment in each product line code. In the method, machine-readable indicia are encoded, in the computerized client-server system, with coded identifiers for each of the well service equipment. Each coded identifier at least includes the product line code, the operational classification code, and the unique identification code for the respective well service equipment. In the method, the encoded machine-readable indicia are physically associated with the respective well service equipment, and tracking information is associated, in the one or more databases, with the coded identifiers for each of the well service equipment. A design list is compiled, at a server side of the computerized client-server system, to implement a given well service using a plurality of given well service equipment at a given well site. In the method the given well service equipment for the given well service at the given well site is remotely tracked, at the server side of the computerized client-server system, using the coded identifiers of the encoded machine-readable indicia by: dispatching the given well service equipment in the given design list from a dispatch site to the given well site by verifying the encoded machine-readable indicia for the given well service equipment; obtaining, from a client side of the computerized client-server system, a dispatched list of the encoded machine-readable indicia for the given well service equipment obtained at the given well site to implement the given well service; and verifying the dispatched list to the design list.

The described implementations may also include one or more of the following features. Remotely tracking in the method at the server side may include: obtaining, at the server side from the client side, a demobilized list of the encoded machine-readable indicia obtained at the given well site to demobilize the given well service equipment from the well site; and verifying the demobilized list to the design list. The method may further include: obtaining, at the server side, servicing information of the given demobilized well service equipment; and associating, in the one or more databases, the obtained servicing information with the tracking information for the given demobilized well service equipment.

In the method, quantity codes can be coded, in the one or more databases, for each of the well service equipment having a plurality of associated items. Each quantity code can identify a total number of the associated items for the respective well service equipment and can identify a given number of the associated item of the respective well equipment in the total number of items. Each of the coded identifiers for each of the well service equipment can further include the quantity code. Accordingly, the method may include locally tracking, at the client side of the computerized client-server system, the given well service equipment for the given well service at the given well site using the coded identifiers of the encoded machine-readable indicia by: decoding the coded identifiers from the encoded machine-readable indicia of the given well service equipment; verifying directly from the quantity codes that the given numbers of the associated items of a respective one of the well service equipment fail to match the total number of the items identified; and producing a warning in response to the verification.

In the method, inspection codes can be coded, in the one or more databases, for each of the well service equipment. Each inspection code can identify an inspection date for the respective well service equipment. Each of the coded identifiers for each of the well service equipment can further include the inspection code. Accordingly, the method may include locally tracking, at the client side of the computerized client-server system, the given well service equipment for the given well service at the given well site using the coded identifiers of the encoded machine-readable indicia by: decoding the coded identifiers from the encoded machine-readable indicia of the given well service equipment; verifying directly from the inspection codes that the inspection date of a respective one of the given well service equipment fails outside a predefined time period; and producing a warning in response to the verification.

In the method, the given well service equipment for the given well service at the given well site can be locally tracked, at the client side of the computerized client-server system, using the coded identifiers of the encoded machine-readable indicia by: compiling, at the client side, the dispatched list of the encoded machine-readable indicia for the given well service equipment obtained at the given well site to implement the given well service; and uploading the dispatched list from the client side to the server side of the computerized client-server system for the verification against the design list. When compiling, at the client side, the dispatched list of the encoded machine-readable indicia, the method may include locally reading the encoded machine-readable indicia at the client side; and locally storing the coded identifiers at the client side.

In the method, locally tracking, at the client side, the given well service equipment for the given well service may further include: compiling, at the client side, a demobilized list of the encoded machine-readable indicia for the given well service equipment for the given well service to demobilize from the given well site; and uploading the demobilized list from the client side to the server side of the computerized client-server system for verification against the design list.

In the method, the product line codes can be associated with one or more of drilling, completions, artificial lift, tubular running services, wireline, cementation products, liner hangers, intervention tools, drilling services, and software; the operational classification codes can be associated with one or more of function of equipment, rig up equipment, downhole equipment, surface communication system, rig floor equipment, slips and tubular handling, top drive and elevator, pressure control equipment, radioactive source/HAZMAT, subsurface system, pump system and mud pit, crane and mast operations, ready box/tool box, hydraulic power unit, and auxiliary equipment; and the unique identification codes can be associated with capital asset management information.

In the method, physically associating the encoded machine-readable indicia with the respective well service equipment may include affixing at least one of scannable codes, quick response (QR) codes, bar codes, two-dimensional matrix codes, and radio frequency identification (RFID) devices on the respective well service equipment.

In the method, associating the tracking information with the coded identifiers for each of the well service equipment may include maintaining one or more of usage information, servicing information, and testing information of the well service equipment.

In the method, compiling, at the server side of the computerized client-server system, the design list to implement the given well service using the given well service equipment at the given well site further may include providing one or more graphical user interfaces at the server side, the one or more graphical user interfaces being accessible by the client side and including information associated with the design list, the given well service, and the given well service equipment. Method where encoding the machine-readable indicia with the coded identifiers may include encoding at least one of scannable codes, quick response (QR) codes, bar codes, two-dimensional matrix codes, and radio frequency identification (RFID) devices with the coded identifiers.

Other aspects can include one or more corresponding systems, apparatus, and devices, each configured to perform the actions of the disclosed methods. For example, a programable storage device can be implemented in a computerized client-server system for monitoring well service equipment used in performing well services at well sites. The programmable storage device can have program instructions stored thereon for causing a programmable control device to perform the method disclosed herein.

In another example, a computerized system of a client-server architecture may include a database component, an interface, and a server component. The database component can store product line codes for each of a plurality of product lines covering well service equipment, operational classification codes for each of a plurality of operations in each product line, and unique identification codes for each of a plurality of the well service equipment in each product line. The interface component can be configured to communicate with a client side of the client-server architecture. The server component can be in operable communication with the database component and the interface component. The server component can be configured to: encode machine-readable indicia with coded identifiers for each of the well service equipment, each coded identifier at least including the product line code, the operational classification code, and the unique identification code for the respective well service equipment; associate tracking information with the coded identifiers for each of the well service equipment; compile a design list to implement a given well service using a plurality of given well service equipment at a given well site; receive a dispatched list of the given well service equipment obtained at the given well site to implement the given well service; and verify the dispatched list to the design list to remotely track the given well service equipment for the given well service at the given well site using the coded identifiers of the encoded machine-readable indicia.

The foregoing summary is not intended to summarize each potential embodiment or every aspect of the present disclosure.

### BRIEF DESCRIPTION OF THE DRAWINGS

FIG. 1 schematically illustrates a system according to the present disclosure.

FIG. 2 schematically illustrates a system according to the present disclosure.

FIG. 3 diagrams an example workflow for a well service in which the disclosed system is used.

FIG. 4A illustrates a flowchart of server-side process in the well service workflow according to the present disclosure.

FIG. 4B illustrates a flowchart of client-side process in the well service workflow according to the present disclosure.

FIG. 5 diagrams a coded identifier according to one example.

FIG. 6 diagrams a process of decoding and processing information from a coded identifier.

FIG. 7 schematically illustrates a matrix of product line codes and operational classification codes relative to an example implementation of equipment.

FIGS. 8A8B illustrate flowcharts of the dispatch of equipment according to the present disclosure.

FIGS. 9A-9B illustrate flowcharts of the service execution according to the present disclosure.

FIG. 10 illustrates a flowchart of the demobilization of equipment according to the present disclosure.

FIG. 11A shows an example of a tubular running services rig-up confirmation window.

FIG. 11B shows an example of a drilling services rig-up confirmation window.

FIG. 12 diagrams a process according to the present disclosure.

FIG. 13 shows an example user interface having an asset build sheet for a particular well service job of a client.

FIG. 14 shows an example user interface having a dispatch list for a well service job for a customer.

FIG. 15A shows an example user interface having an operation report with tool usage in a well service job for a customer.

FIG. 15B shows an example user interface having an operation report for a well service job for a customer.

### DETAILED DESCRIPTION OF THE DISCLOSURE

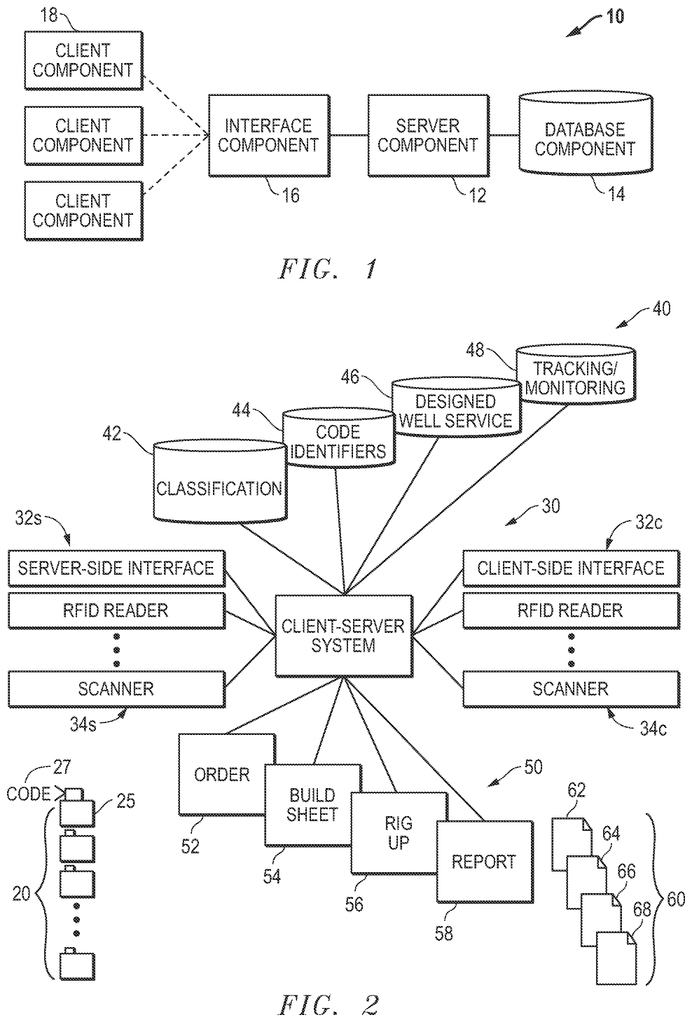

FIG. 1 schematically illustrates a computerized system 10 according to the present disclosure. As shown in this example, the computerized system 10 can have a client client-server architecture within networked environments. Tasks, resources, and responsibilities can be distributed between the client side and server side of the architecture.

In general, the server side of the system 10 includes a server component 12, a database component 14, and an interface component 16. Each component 12, 14, 16 can include multiple modules and systems and can be centralized or decentralized in the network environment(s). In the context of the present disclosure, the server side corresponds to a well service provider that provides well service equipment to clients (customers) to perform various types of well services.

The client side of the system 10 includes client components 18, which can be operated on end-user devices, such as personal computers, laptops, smartphones, tablets, or embedded systems. The client components 18 can also include specific well service equipment, software, tools, and the like provided by the well service provider.

The interface component 16 of the system 10 can include user interfaces and other end-user or customer-facing components of the architecture. These elements can include desktop applications, web browsers, mobile apps, or any device or software that initiates requests to access resources or services. The interface component 16 can use any appropriate communication protocols (e.g., HTTP, TCP/IP, WebSocket, etc.) for communication between the server and client components 12, 18. Any appropriate network infrastructure can be used, such as Local Area Network (LAN), Wide Area Network (WAN), the Internet, etc. In this way, communication between clients and servers can use standardized communication protocols, such as HTTP/HTTPS for web-based applications or protocols like RPC (Remote Procedure Call) for distributed systems.

The server component 12 includes one or more servers, computers, software systems, and other equipment that store, manage, and provide resources or services. For example, the database component 14 can include resources, such as databases, files, applications, and the like. The server-side components 12, 14, 16 can also be hosted in a cloud-based environment.

The server-side components 12, 14, 16 can also include mobile devices, phones, tablets, computers, and the like, which can be connected by a network connection (wired or wireless) to the cloud-based environment. Using the mobile devices, personnel can perform dispatch tasks (add items to asset management system, dispatch equipment from the facility, print required documentation, photograph equipment being shipped, etc.). Personnel can also perform field reporting tasks (rig inventory, operational time tracker, rig-up report, etc.) and can perform tool tracking tasks (input equipment information, general coded identifiers, etc.),

The database component 14 includes any appropriate type of database. For example, these databases can use relational databases (e.g., MySQL), NoSQL databases (e.g., MongoDB), or distributed databases (e.g., Cassandra).

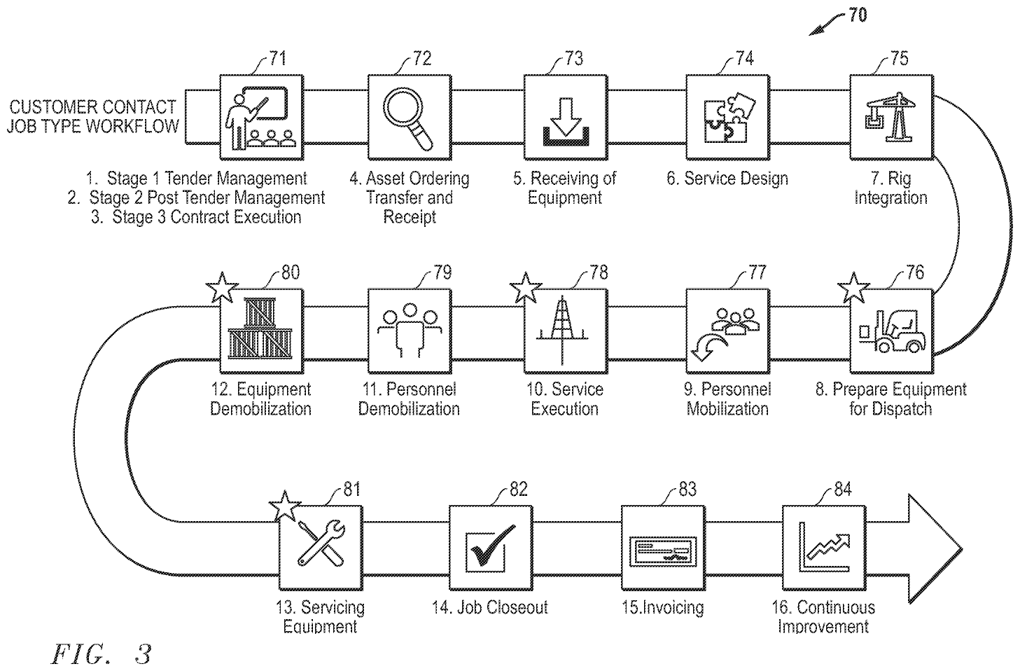

FIG. 2 schematically illustrates a system 30 of the present disclosure in more detail. As noted above, the system 30 is used by a well service provider and clients to monitor, verify, and track well service equipment 20 used to perform well services at well sites. When a client (customer) requires a well service, the client access the system 30 through the client-side interfaces 32c, such as web-based applications. Designers at the service provider can then design the best implementation by selecting the well service equipment 20 (e.g., well service tools and other resources) required to perform the well service.

The available well service equipment 20 can include many different versions, sizes, characteristics, and the like. Much of the well service equipment 20 may appear similar, which can result in confusion or errors when dispatching, handling, assembling, and installing the well service equipment 20 in the field at a client's well site. At the well site, for example, reviewing and verifying the well service equipment 20 can be time consuming and difficult.

Moreover, the designed well service may require different service operations and equipment 20 to be used from disparate product lines of the service provider. For example, pumping equipment and wireline equipment, which can be from different product lines of the service provider, may be needed to perform the well service for the client.

To avoid errors and to facilitate the well service, each item of well service equipment 20 is given a machine-readable indicium 25 that has a coded identifier 27. Each coded identifier 27 is unique to each item and includes a relationship to the product line and service operation of the item. As disclosed herein, the machine-readable indicium 25 can be an RFID tag, and the coded identifier 27 can include identifying information of the equipment 20 to which it is assigned or associated.

To avoid errors and facilitate handling and processing, the system 30 disclosed herein creates a relationship between the well service equipment 20 and the operations in which it is used and further creates a relationship between the design for the well service and the selected well service equipment 20 selected to perform the designed well service.

To do this, the disclosed system 30 uses various operational applications or features 50, such as an order feature 52 to handle the order of well services by clients; a build feature 54 to select, build, and design the implementation for a well service; a rig up feature 56 to facilitate the rig up of the designed implementation; and a reporting feature 58 to deal with monitoring, tracking, modifications, and other communications. Various reports, lists, communications, and the like (generally reports 60) can be compiled, exchanged, and verified between the client and server side of the system 30. These reports 60 can include a design list 62 of given equipment designed to implement a given well service for a client, a dispatch list 64 of the given equipment 20 and related information (documentation, installation manuals, etc.) dispatched from the well service provider and received at the client's well site, a demobilization list 66 of equipment 20 to be demobilized from the well site, and servicing information 68 for service information of equipment 20.

Server-side interfaces 32s allow users at the service provider to access the operational features 50 of the system 30, while the client-side interfaces 32c allow clients (customers) to access the operational features 50 of the system 30. Various monitoring and tracking components 34s, 34c can be used for monitoring and tracking the well service equipment 20 both at the server-side and the client-side of the system 30. These components 34s, 34c can include devices for reading machine-readable indicia 25 and decoding the coded identifiers 27 associated with the well service equipment. Examples of the components 34s, 34c include RFID readers, optical scanners, cameras, etc.

For example, the components 34s, 34c of the system 10 can include portable readers, such as radio frequency identification RFID readers, which can link to the mobile device, with a wired or wireless connection, such as a BLUETHOOTH connection. The portable readers can read the coded identifiers, such as encoded in the RFID tags, used on the equipment.

Different types of RFID tags can be used. The RFID tags or devices come in two broad categories. An active RFID tag has its own power source (e.g., a battery) and is configured to continuously transmit its data payload. When it comes within range of an Active RFID detector, which can be configured as a “listen only” device, the Active RFID detector will detect the transmitted signal and respond according to its program. By contrast, a passive RFID tag does not have its own power source and is instead powered by a passive RFID tag reader. Generally, a passive RFID tag reader emits a high frequency electromagnetic field. This field stimulates a coil in the passive RFID tag that then charges a capacitor within the passive tag that serves as the passive tag's power source. Once the capacitor is charged, the passive tag begins transmitting its payload until the charge in the capacitor is depleted. The passive RFID tag reader can then detect this transmitted signal. The portable reader can be a tablet device having 2-D image and RFID capable electronics. The RFID tags can be affixed to well service equipment using adhesive, machining, fixtures, etc.

Finally, to provide the operational features 50 and reports 60, the disclosed system 30 includes databases 40 for storing classifications 42 of the well service equipment 20, code identifiers 44 for the well service equipment 20, designed implementations 46 of well services, and tracking and monitoring information 48. The relationship between the various elements of the disclosed system 30 will be described in more detail below.

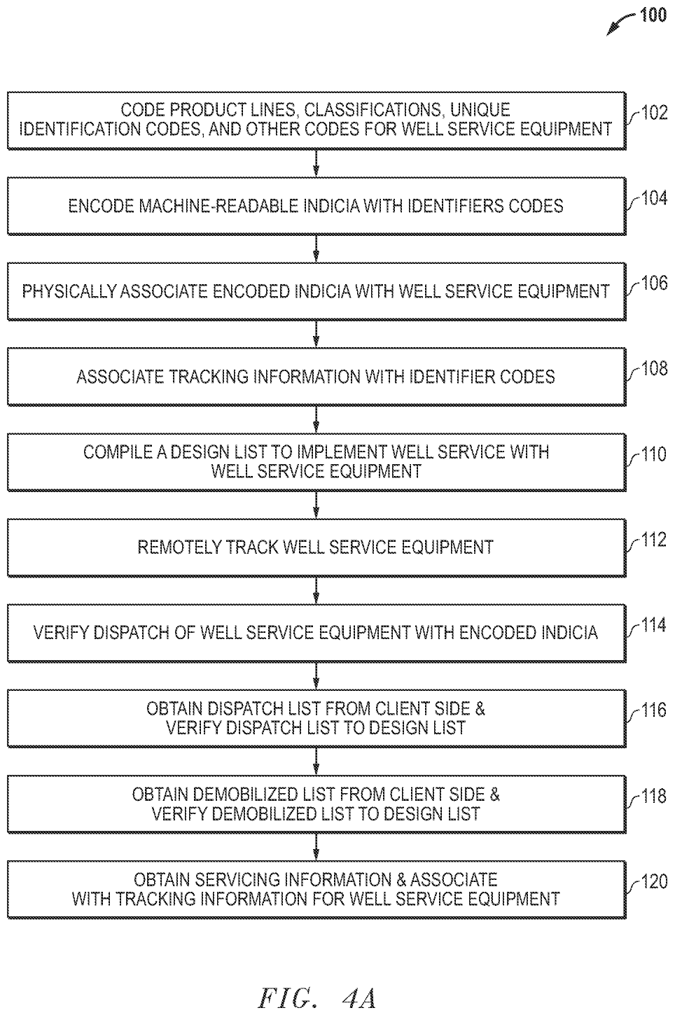

FIG. 3 diagrams an example workflow 70 for a well service in which the disclosed system 30 is used. The workflow 70 to perform a typical well service (i.e., job) involves a number of steps, which can benefit from the disclosed system 30. After ordering and other preliminary steps are completed (steps 71, 72, 73), the implementation for the well service job is designed by the service provider (step 74), and the equipment 20 is selected and configured to integrate into a rig or other existing infrastructure at the client's well site (step 75).

Once ready, the required equipment 20 is prepared and dispatched to the client's well site (step 76), and personnel are mobilized (step 77). The dispatch process involves multiple steps to ensure proper organization and shipping of the correct well service equipment 20. The features of the disclosed system 30 facilitate this dispatch process.

Once the well service equipment 20 has been dispatched to the client's well site, the equipment 20 can be installed, and the well service can then be executed at the site (step 78). As expected, the receipt of the dispatched equipment and the installation at the site involve multiple steps to ensure that the correct well service equipment 20 is received and that the proper implementation can be installed. Features of the disclosed system 30 facilitate this execution process.

Once the well service is complete, the equipment 20 and personnel are demobilized for return to the well service provider (step 79 and 80). The demobilization process involves multiple steps to ensure proper organization and return of the correct well service equipment 20. Features of the disclosed system 30 facilitate this demobilization process.

Additionally, the well service equipment 20 can be serviced, refurbished, inspected, etc. (step 81), and features of the disclosed system 30 can track this servicing process. Various completion steps can follow the completion of the well service job (steps 82-84). In the workflow 70, features of the disclosed system 30 disclosed in more detail below can be used in monitoring and tracking the dispatch process (step 76), the execution process (step 78), the demobilization process (step 80), and the servicing process (step 81) of the workflow 70.

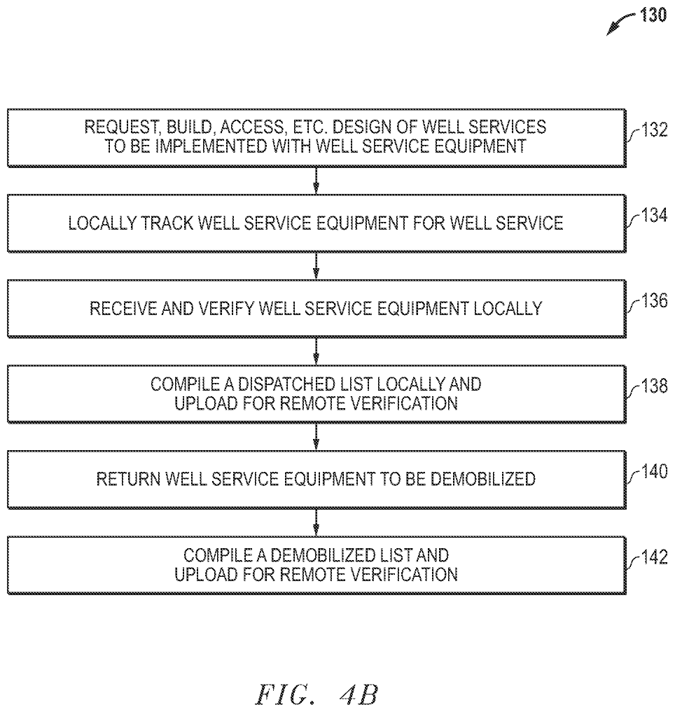

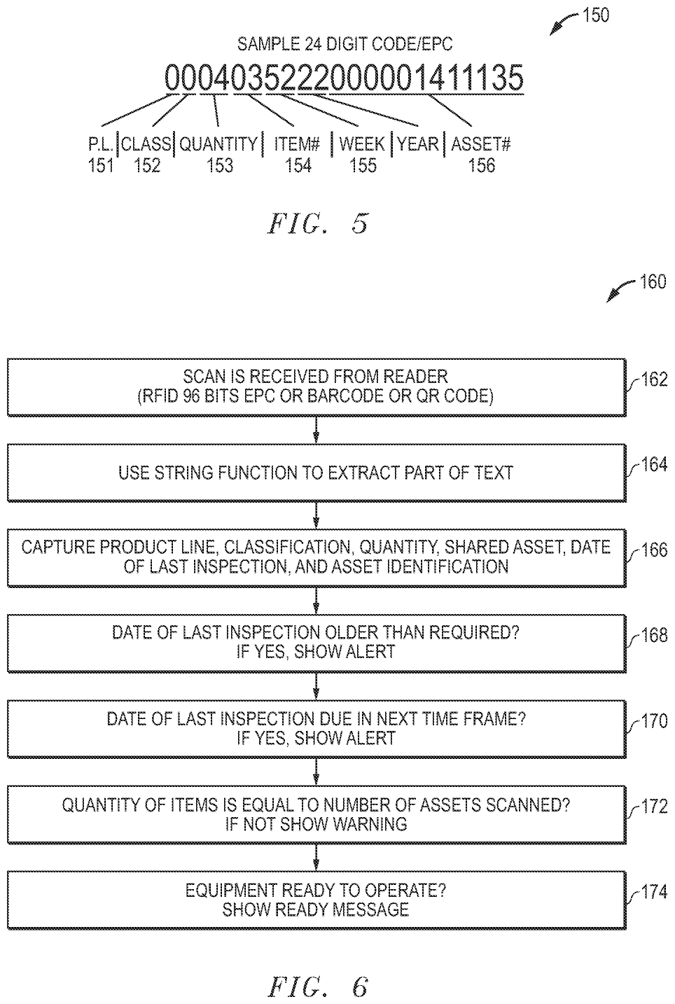

In particular, FIG. 4A illustrates a flowchart of server-side process 100 in the well service workflow according to the present disclosure. The steps of the server-side process 100 are performed in a method implemented in the computerized client-server system (30) of monitoring well service equipment (20) used in performing well services at well sites. (Reference to element numerals from previous figures are provided in the discussion below.)

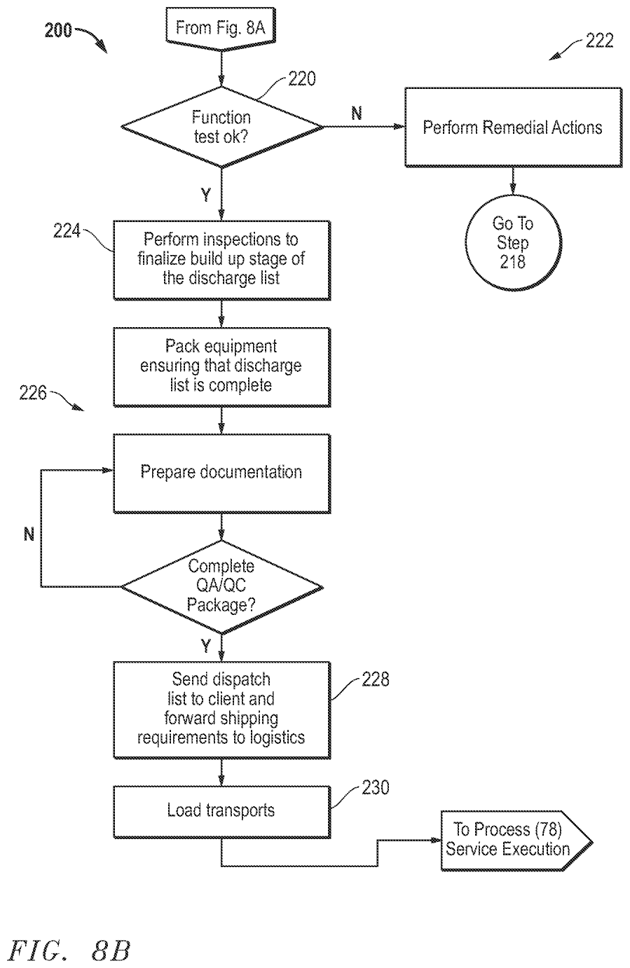

As noted, the disclosed system 30 includes a relationship between the well service equipment 20 and the operations in which the equipment 20 is used. To produce the relationship, various organizational codes are stored in one or more databases 40 of the computerized client-server system 30 (Block 102). In particular, product line codes are coded for each of a plurality of product lines covering the well service equipment 20. Operational classification codes are coded for each of a plurality of operations in each product line, and unique identification codes are coded for each of a plurality of the well service equipment 20 in each product line. (By way of example, further details of a relationship matrix between product lines and operational classifications are described below with respect to FIG. 7.)

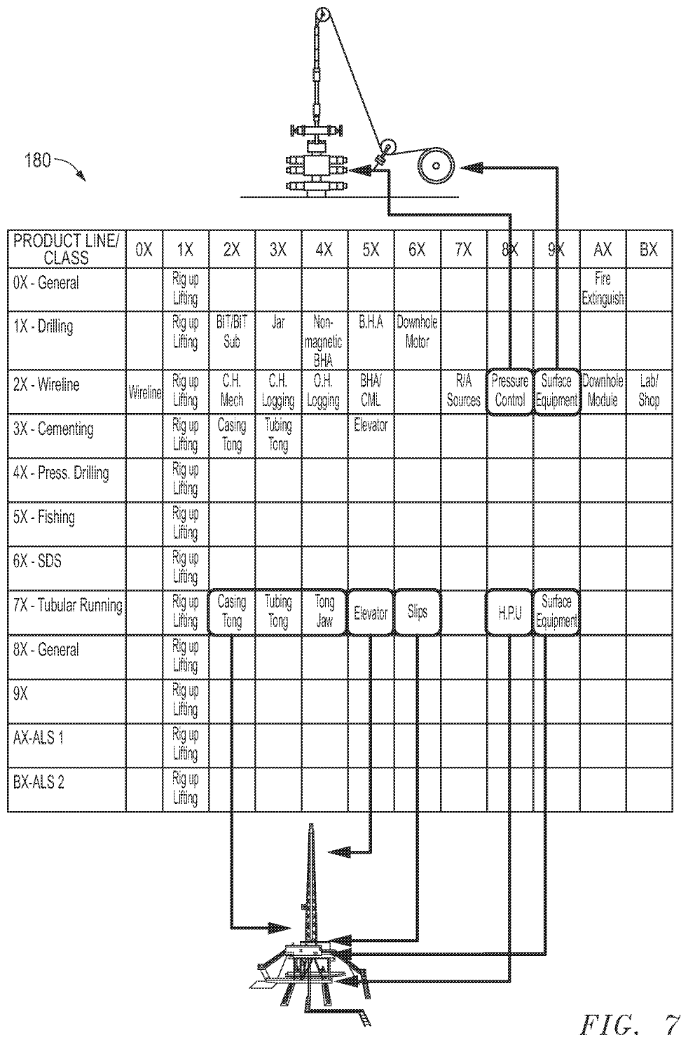

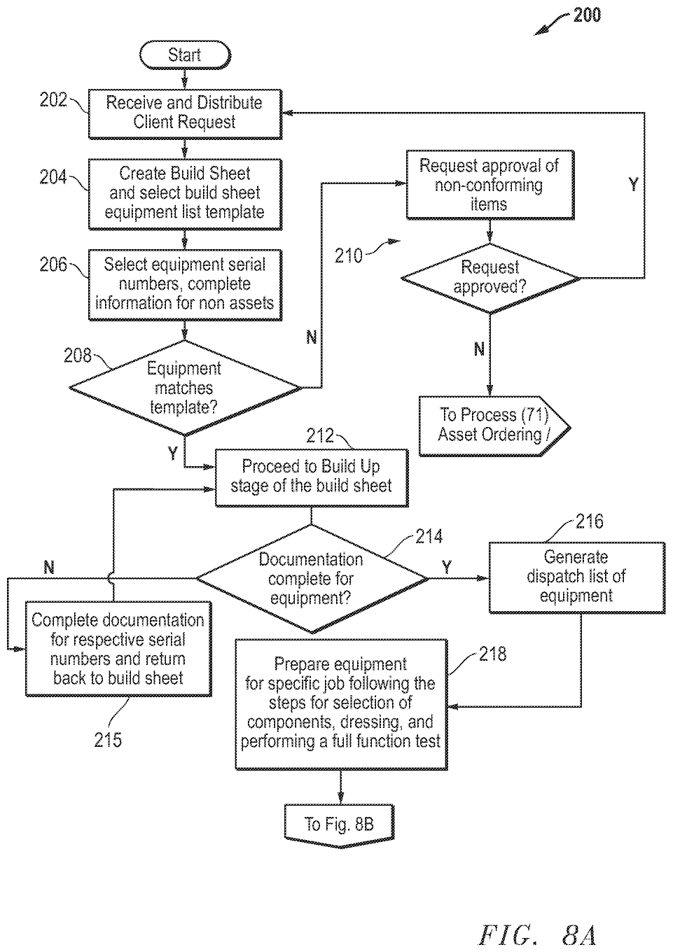

Additional information can also be coded. For example, quantity codes can be coded for each of the well service equipment 20 having a plurality of associated items to be used in a set. Each quantity code can identify a total number of the associated items for the respective well service equipment 20 in the set, and the quantity code can identify a given number of an associated item of the set with respect to the total number of items for the set. For example, a quantity code can indicate that a particular piece of equipment 20 is a first piece in a set of three pieces. In addition to quantity information, inspection codes can be coded for the well service equipment 20. The inspection code can identify an inspection date for the respective well service equipment. (By way of example, further details of an example coding arrangement are described below with respect to FIGS. 5 and 6.)

In the server-side process 100 of FIG. 4A, machine-readable indicia 25 is encoded with coded identifiers 27 for each of the well service equipment 20 (Block 104), and the encoded machine-readable indicia 25 are physically associated with the respective well service equipment 20 (Block 106).

Each coded identifier 27 can at least include the product line code, the operational classification code, and the unique identification code for the respective well service equipment 20. The coded identifiers 27 can also include the quantity code, the inspection code, and other information as desired.

The machine-readable indicia 25 encoded with the coded identifier 27 for each piece or item of well service equipment 20 can be a scannable code, a quick response (QR) code, a bar code, a two-dimensional matrix codes, or a radio frequency identification (RFID) device, each of which can encode the coded identifier 27 for the respective item of equipment 20. The machine-readable indicia 25 can be affixed, attached, embedded, or the like directly to the well service equipment 20 so that each item can be directly monitored and tracked. Various techniques are available for associating such machine-readable indicia 25 with well service equipment 20 and are not detailed herein for brevity.

In the server-side process 100 of FIG. 4A, tracking information is also associated in the system 30 with the coded identifiers 27 for each of the well service equipment 20 (Block 108). As noted, the coded identifier 27 includes discrete, directly readable information, such as product line, operation, quantity, inspection, and unique identification for an item of well service equipment 20. Associated information about usage, manufacturer, servicing, etc. for the item of well service equipment 20 can be stored relationally in the databases 40 of the disclosed system 30.

In the design process in which the well service is designed by the service provider for a client, a design list 62 is compiled at the server side of the computerized client-server system 30. The design list 62 includes the coded identifiers 27 for given well service equipment 20 selected to implement a given well service at a given well site (Block 110).

The design list 62 that includes coded identifiers 27 encoded in the machine-readable indicia 25 is then used to remotely track the given well service equipment 20 for the given well service at the given well site (Block 112). In the dispatch process in which the well service equipment 20 in the design list 62 is dispatched from one or more dispatch sites to the well site, the encoded machine-readable indicia 25 for the well service equipment 20 is used to verify that the correct equipment is dispatched (Block 114).

Once the equipment 20 is dispatched, the server side can obtain a dispatch list 64 having the coded identifiers 27 of the encoded machine-readable indicia 25 received from the client side of the computerized client-server system 10. The dispatch list 64 includes the information of the equipment 20 received by the client at the well site. Accordingly, the dispatch list 64 can be verified against the design list 62 for any discrepancies (Block 116). Further features of the disclosed system 30 can enable clients to access and update information about the installation and execution of the well service with the dispatched equipment 20.

Once the well service is completed, the server side can obtain a demobilization list 66 having the coded identifiers 27 of the encoded machine-readable indicia 25 for the given well service equipment 20 to be demobilized from the well site. The demobilization list 66 includes the information of the equipment 20 to be returned by the client at the well site. Accordingly, the system 30 can compare the demobilization list 66 against the design list 62 and can verify what equipment 20 needs to be returned to the service provider (Block 118).

As noted, the returned equipment 20 may go through a servicing process. In this case, the server side can obtain servicing information 68 of the given demobilized well service equipment 20, and the obtained servicing information 68 can be properly associated with the tracking information in the system's databases 40 (Block 120).

Having a description of the server-side process 100, FIG. 4B illustrates a flowchart of a client-side process 130 in the well service workflow according to the present disclosure. (Reference to element numerals from previous figures are provided in the discussion below.)

As noted, the client can order a well service and can use features of the system 30 to request, build, access, etc. the design of a well service to be implemented with well service equipment 20 (Block 132). In any of the communications between the server and clients, one or more graphical user interfaces at the server side can being accessible by the clients and can include information associated with the design list, the given well service, and the given well service equipment 20. Updates, reports, and other actions can be performed through the user interfaces. (By way of example, further details of user interfaces are described below.)

Additionally, the client can use local devices or components 34c, such as RFID readers, scanners, and computer equipment to read the machine-readable indicia 25, to decode the underlying coded identifiers 27, and to process the information against locally stored information, such as design lists 62, dispatch lists 64, implementation details, demobilization lists 66, and the like.

When the client receives dispatched equipment 20, installs equipment 20, demobilizes equipment 20, and the like, the client can communicate the coded identifiers 27 of the encoded machine-readable indicia 25 to the server-side for remote tracking and monitoring. Moreover, the client can use the coded identifiers 27 of the encoded machine-readable indicia 25 to locally track given well service equipment 20 for the given well service at the client side of the computerized client-server system 30. For example, the client can decode the coded identifiers 27 from the encoded machine-readable indicia 25 of the given well service equipment 20. Using the decoded information, the client can locally verify the equipment 20 received against the design list 62 (Block 134) and/or can compile and upload a receipt of the dispatched equipment 20 for remote verification from the server side (Block 136).

The inspection codes of the coded identifiers 27 can be directly checked to ensure that the inspection date of a given item of equipment 20 does not fail outside a predefined time period. If it does, then a warning can be produced locally for the client. Similarly, the quantity codes can be directly checked to ensure that the given number of the associated items of set match the total number of the items identified and received. If not, then a warning can be produced. For the demobilization of the equipment 20, the client can locally verify the equipment to be demobilized (Block 140) and/or can compile and upload a list of the demobilized equipment for remote verification from the server side (Block 142).

FIG. 5 diagrams a coded identifier 150 according to one example, and FIG. 6 diagrams a process 160 for locally decoding and processing the information from the coded identifier 150. (Reference to element numerals from previous figures are provided in the discussion below.) As noted, the system 30 uses coded identifiers 150 for the assets (e.g., equipment, tools, etc.). The coded identifier 150 are coded with various classifications that provide underlying details of the associated asset. Each coded identifier 150 is then coded in machine readable indica (25), such as an RFID tag, which is incorporated into, attached to, or otherwise associated with the equipment (20).

The example coded identifier 150 in FIG. 5 includes a 24-digit code, which can be a type of universal electronic product code to unique identity each item of equipment across the well service provider and over time. The coded identifier 150 holds information about seven classifications. Although various classifications can be used, one particular example includes a product line code 151, an operational classification code 152, a quantity code 153, an item code 154, time code 155 (week and year), and unique asset identification code (e.g., capital asset management number) 156.

The service provider can have a number of various product line codes 151, such as product lines for drilling, completions, artificial lift, tubular running services, wireline, cementation products, liner hangers, intervention tools, drilling services, software, etc. One coded digit (e.g., a hexadecimal number) in the coded identifier 150 can code up to sixteen product line codes 151 for the service provider. The product lines can be simplified or organized as desired.

The operational classification code 152 can be used for simple classifications of the equipment 20 as used in operations. The operational classification codes 152 of the present disclosure can include: function of equipment, rig up equipment, downhole equipment, surface communication system, rig floor equipment, slips and tubular handling, top drive and elevator, pressure control equipment, radioactive source/HAZMAT, subsurface system, pump system and mud pit, crane and mast operations, ready box/tool box, hydraulic power units, auxiliary equipment, and the like for a well service providers available operations.

Each product line code 151 can have its own operational classification codes 152. For example, the product line code 151 for drilling can include operational classification codes 152 such as rig-up and lifting; bit or bit sub; jar; non-magnetic bottom hole assembly (BHA); BHA; downhole motor, etc. In another example, the product line code 151 for wireline can include operational classification codes 152 such as rig-up and lifting, closed hole mechanical, closed hole logging, open hole logging, BHA/CML, pressure control, surface equipment, downhole module, lab/shop, etc. In yet another example, the product line code 151 for tubular running surfaces can include operational classification codes 152 such as rig-up and lifting, tong/wrench, jaw, elevator/spider, slip/carrier, transport/position, hydraulic power unit, surface equipment, stabbing, bails, etc.

Many assets of equipment, tools, and the like may come in sets so the quantity code 153 defines the quantity of items in a set. The digit “01” would indicate a single item asset, whereas the digit “03” would indicate an asset coming in a set of three. The two available digits (e.g., hexadecimal numbers) of the quantity code 153 would allow for a set of up to two hundred and fifty-six items. When an asset comes as part of a set, the item code 154 defines the number of the given item within the given asset set.

The digits for the time code 155 can be used in a number of ways to signify manufacture date, last inspection date, etc. In this example, the time code 155 includes Week and Year for the date of last inspection (if required). A default value of “0000” can be used if the information is not required.

Finally, the remaining digits of the coded identifier 150 a used for the unique asset identification code 156. For example, the unique asset identification code 156 can be a capital asset management number, which can be customized for each of the various product lines or different databases of the system.

Existing capital asset management systems classify assets based on branch plant and e-node and are targeted for financial purposes. An example capital asset management system includes an Oracle database system offered by J. D. Edwards. There are several challenges to a well service provider, given the multiple product lines offered, the different types of operations available, and the types of capital assets that need management. Existing capital asset management techniques do not classify equipment according to distinctions best suited for a well service provider. Instead and as noted, existing capital asset management techniques classify equipment by branch plant and e-node, and the existing classifications are targeted for financial purposes and not operational tracking. In any event, the unique asset identification information (e.g., capital asset identification number) 156 of the present coded identifier 150 can be associated in the system's databases 40 with typical asset information, such as branch plant, item number, inventory part number, asset description, product line, equipment class, manufacturer, manufacturer serial number, ownership, etc.

However, to improve tracking and monitoring, the system and method of the present disclosure uses the product line codes 151 and operational classification codes 152 in conjunction with the unique asset identification code 156 of the equipment 20. This relationship allows the unique asset identification used in the coded identifier 150 of the present system to be targeted for operational purposes to manage and track the equipment 20 used in well service operations. Operational classifications of the equipment 20 are delineated for the different categories of tools and equipment 20 for the product lines.

For example, a tubular running service product line may have a category of tongs that can be used for running tubulars. The tong category can have subcategories of power, mechanical (manual), and specialized based operation. The tong category can further be delineated based on sizes of jaws for different tong sets and the like. As will be appreciated, the unique asset identifications used in the coded identifiers of the present system are delineated with whatever fine particularity is required to track/monitor the build, rig up, and operation of the various assets that are used on given jobs.

FIG. 6 diagrams a process 160 of decoding and processing information from a coded identifier (150). The machine-readable indica (25) is read using a device, and the coded identifier (27, 150) is detected and decoded (Block 162). For example, an RFID reader can scan an RFID tag encoding the coded identifier (150). The information (digits) of the coded identifier (150) are obtained (Blocks 164, 166). For example, software can use a string function to extract product line, classification, quantity, and other digits of the coded identifier (150). As disclosed herein, the decoded information can be used in the system for verification purposes against lists and databases. Additionally, a user of the device can directly use the decoded information to determine if there are any issues with the equipment being scanned even if communications are not currently available with the service provider.

For example, a user can use the reader to determine that the date of last inspection from the coded identifier (150) is older than required, and the user can be shown an appropriate alert (Block 168). Similarly, a determination can be made that the expiration of the last inspection is due within the present time frame of the well service, and the user can be shown an appropriate alert (Block 170). A determination can determine that the quantity of items in a set is not equal to the number scanned, and the user can be shown an appropriate alert (Block 172). Otherwise, a user can be shown a ready message when the equipment is ready to operate (Block 174).

FIG. 7 schematically illustrates a matrix 180 of product line codes and operational classification codes relative to an example implementation of equipment. In the disclosed system, product line numbers of the capital asset management database are mapped and assigned to product line name variables for operations. The product line codes are then given a number of operational classification codes. This produces a matrix 180 of product line codes and operational classification codes. The product line/operational codes in the matrix 180 of FIG. 7 are shown for equipment in an example installation of a rig and a wireline system.

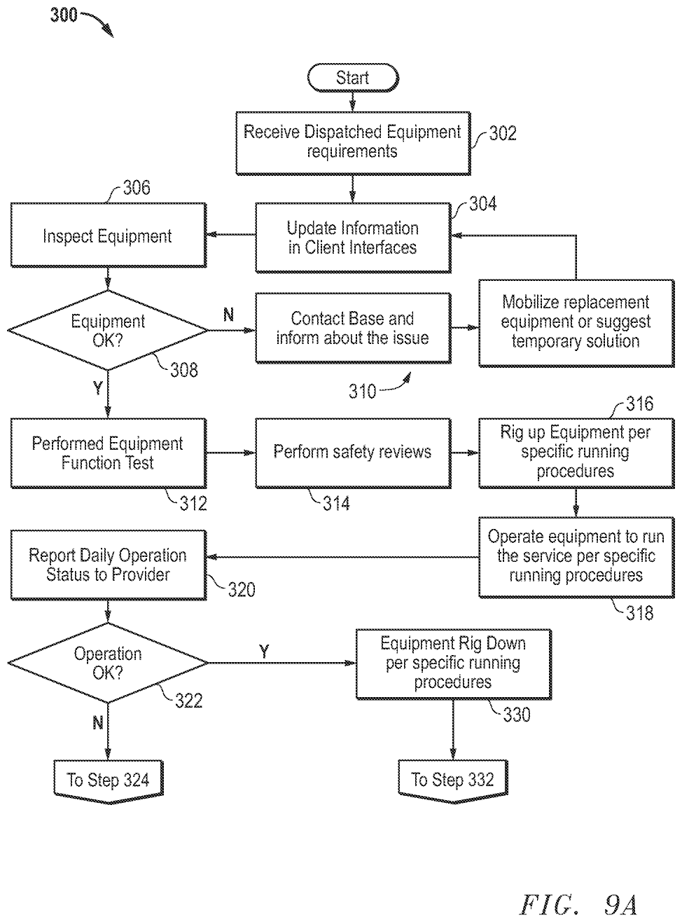

FIGS. 8A-8B illustrate flowcharts of a dispatch process 200 of equipment (20) according to the present disclosure. (Reference to element numerals from previous figures are provided in the discussion below.) The disclosed system 30 receives a client's service request and distributes the request to the appropriate members and system components of the service provider (Block 202). Personnel at the service provider use the interfaces of the disclosed system 30 to create a build sheet for the requested service by selecting a build sheet template having an equipment list for the requested service (Block 204). The build sheet template includes the list of well service equipment 20 designed to implement the well service (i.e., the build sheet template includes the design list 62 of the well service equipment 20 designed to implement the well service).

As the personnel prepare the equipment 20 for dispatch, the personnel use the interfaces of the disclosed system 30 to select equipment serial numbers and other information for the build sheet for design list 62 (Block 206). For any equipment 20 that is not an asset in the system 30, the personnel complete the needed information for these assets. In these steps, the personnel can read the RFID tags or other machine-readable indica 25 to locate serial numbers from the coded identifiers (27) for the well service equipment 20 being prepared for dispatch and can use the decoded information to populate containers in the build list interface.

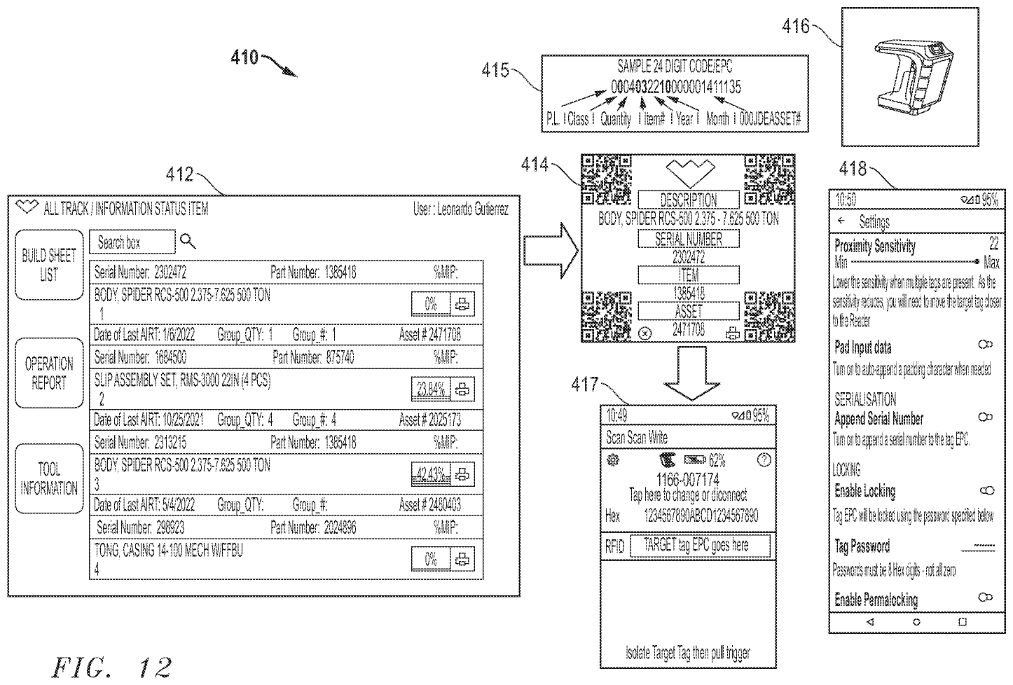

When preparing the equipment for dispatch, personnel can update the machine-readable indica 25 of the equipment 20 with the current data. For example, FIG. 12 diagrams a process 410 according to the present disclosure. A tool information window 412 of the user interface is opened, which contains information on the equipment. The tool or equipment 20 to be updated is located using a manual search or by scanning the machine-readable indica 25 (e.g., the RFID tag) using a device 416. For example, the device 416 can be an optical reader, a camera, a scanner, an RFID reader, an RFID reader/writer, etc.

If the device 416 can communicate with the user interface, then the latest data for the equipment 20 can be downloaded to the device 416 for subsequently writing to the machine-readable indicum 25 (e.g., RFID tag). Otherwise, a QR code 414 can be generated, encoding the coded identifier 27 and having the latest data for the equipment 20. The QR code 414 can then be scanned with the read/write device 416. For its part, the device 416 can have user interfaces 417, 418 for configuring information. The device 416 can be placed near the equipment's indicum 25 (RFID tag) to write the updated data to the indicum 25.

In the dispatch process 200 of FIG. 8A, the disclosed system 30 can verify that the coded identifiers read from the equipment 20 match what is required in the template (Decision 208). If not, then approval is required for any non-confirming items (Block 210).

When the build sheet is complete, then the dispatch process 200 proceeds to a build-up stage (Block 212) in which a determination is made if documentation (operating manuals, pictures, etc.) is complete for the pieces of equipment (Decision 214) and the documentation is updated if necessary (Block 215).

A dispatch list 64 is then generated listing the equipment 20 for the well service job (Block 216). Personnel then process each item of equipment 20 for the specific job by selecting the component, dressing it, and performing function tests (Block 218). During these steps, the personnel can access and update the stored information in the discloses system 30 by reading the RFID tags or other machine-readable indica 25 for the equipment 20 as it is processed and handled.

If the function test for an item of equipment fails (Decision 220) as shown in FIG. 8B, then remedial actions are followed to handle the nonconforming item (Block 222). For example, the item may be repaired or replaced. Eventually, inspections are completed to finalize the build-stage of the dispatch list (Blocks 224).

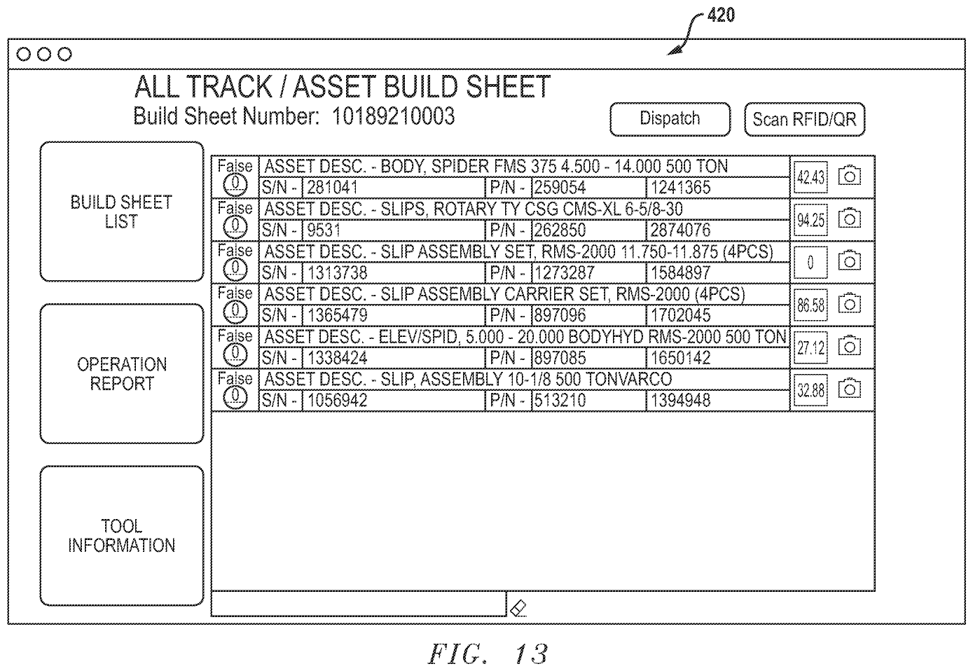

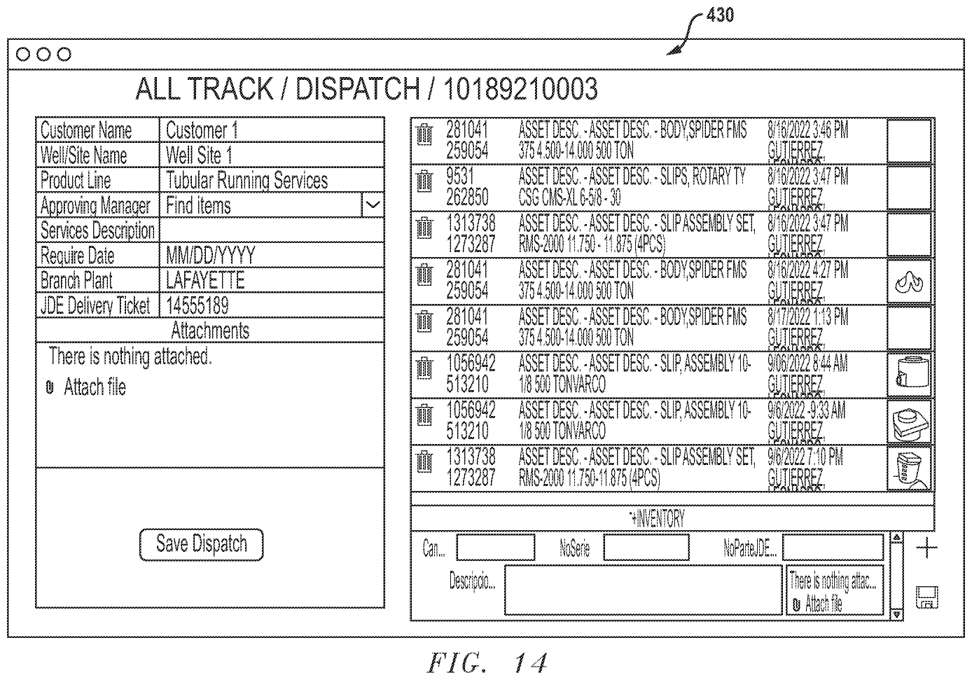

When preparing the equipment for dispatch, for example, personnel compare the equipment 20 prepared for shipping to what is listed on the build sheet having the design list 62 of equipment 20 for the well service job. FIG. 13 shows an example user interface 420 having an asset build sheet for a particular well service job of a client. Finally, in the equipment dispatch, personnel generate a dispatch list 64 of the equipment 20 being shipped to a well site for the well service job. FIG. 14 shows an example user interface 430 having a dispatch list for a well service job for a customer.

In the dispatch process 200 of FIG. 8B, the equipment is then packed (Block 226), ensuring that the dispatch list 64 is complete. During the packing steps, personnel can read the RFID tags or other machine-readable indica 25 and can directly compare the detected equipment 20 against customer request, the design list 62 from the build sheet, and the dispatch list 64 for the shipment.

Documentation is prepared for the customer. The user interfaces of the disclosed system can automate the document packing for customers. Quality controls are performed to check the packaging.

The dispatch list 64 of the equipment 20 is sent out to the client's well site, and the shipping requirements are forwarded to the service provider's logistic personnel (Block 228). The user interfaces of the disclosed system 30 can automate the notifications to logistics and to send the dispatch list 64. Ultimately, the trucks or other transports are loaded to transport the equipment 20 to the client's well site (Block 230).

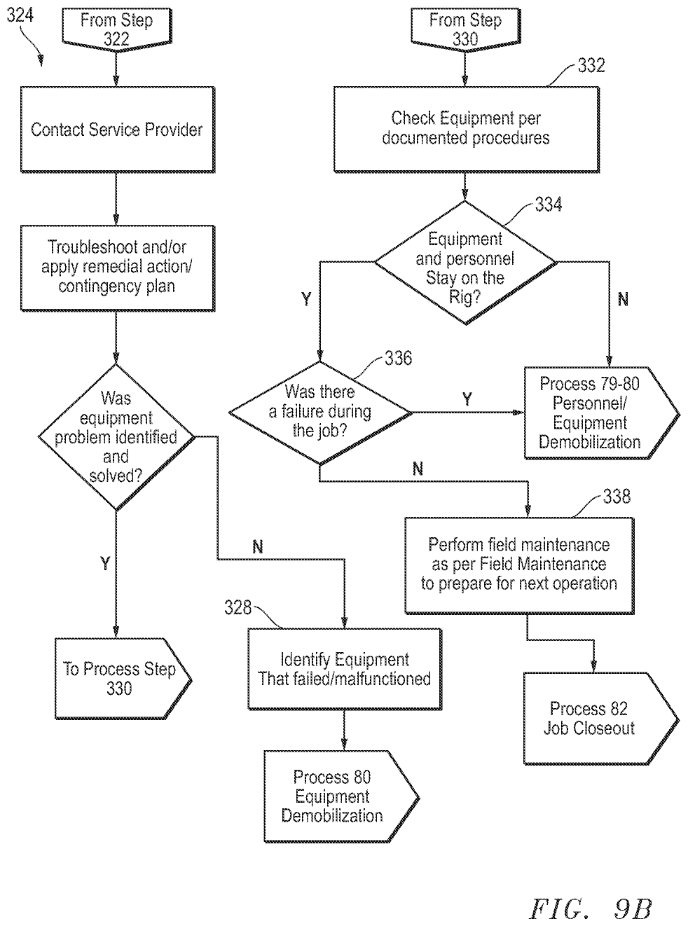

FIGS. 9A-9B illustrate flowcharts of a service execution process 300 according to the present disclosure. The field personnel at the client's well site receive the dispatched equipment 20 (Block 302) and update the system 30 using the user interfaces (Block 304). The equipment 20 is inspected (Block 306 and Decision 308). In these steps, the field personnel read the RFID tags or other machine-readable indica 25 to detect the inventory of the equipment 20 in the field and to directly access the information for the equipment 20 stored in the disclosed system 30. If there are any issues with the equipment 20, the service provider can be notified, and any replacement equipment 20 can be mobilized. The field personnel then perform a number of conventional steps of testing the equipment (Block 312) and performing safety reviews (Block 314).

The equipment 20 is then rigged up according to the designed implementation (Block 316). The field personnel access and use the user interfaces of the disclosed system 30 to track all of the equipment 20 being used, to verify any lifting requirements for equipment 20, to check the rig-up of equipment 20 to the job design, and the like. Direct access to the details can be made by reading the RFID tags or other machine-readable indica 25 of the equipment 20 as it is being handled and rigged up.

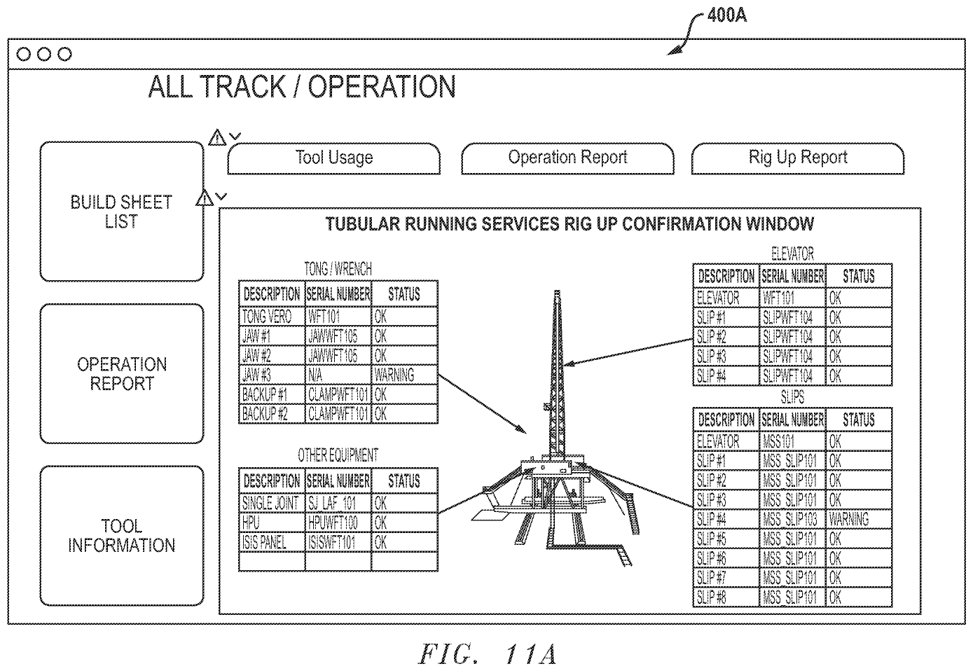

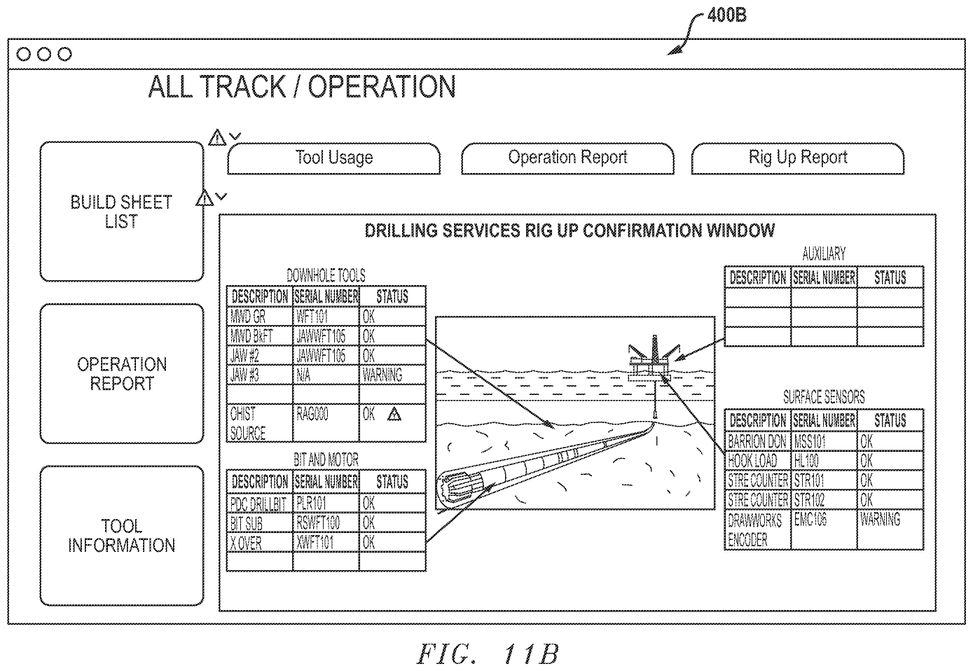

For example, FIGS. 11A-11B illustrate example graphical user interfaces 400A-B showing rig-up confirmation windows, which client personnel can access during service execution. For instance, FIG. 11A shows an example of a tubular running services rig-up confirmation window 400A, showing information on tongs, elevator, slips, and other tubular running service equipment. Meanwhile, FIG. 11B shows an example of a drilling services rig-up confirmation window 400B, showing information on downhole tools, bit and motor, surface sensors, and auxiliary drilling service equipment.

Using the client and services interfaces of the system 30, clients and operators can select assets (equipment, tools, etc.), build implementations to complete various jobs, and access various tool and operation reports. The example rig-up confirmation windows 400A-B for operations are shown and include panels for a build sheet list, operation report, and tool information. Tabs are available to access information on tool usage, rig-up report, and the like. Assets selected can be visualized for easier interpretation. Briefly, the build sheet list can list the equipment used to build an installation to complete a well service job. The operation report can contain information about the tracking and servicing of the equipment 20, and the tool information can provide details of each given asset in the installation. The tool usage tab can access information about the service life of tools, maintenance and testing dates, and other tracking details for the assets. The rig-up report can show how the equipment is rigged up for the installation of the well service.

As shown in the process of FIG. 9A, the equipment 20 is then operated to perform the well service (Block 318). The user interfaces of the disclosed system 30 can track or log times of the equipment 20 for later reporting. Follow-up assessments and reports can then be performed. For example, the disclosed system 30 can transfer daily operation reports to the client's base system (Block 320). If the operation is not successful or sufficient (No at Decision 220), further steps can be taken. Otherwise, once the service is complete, the equipment 20 is disassembled or removed and prepared for demobilization (Block 330).

As shown in FIG. 9B, the disclosed system 30 allows the field personnel to contact the service provider should it be necessary and arrange to troubleshoot and/or apply a remedial action or contingency plan (Blocks 324). The user interfaces of the disclosed system 30 allow the field personnel and service provider to track failures and create quick field reports. If the equipment problem is solved, then the field personnel can proceed as normal. Otherwise, the disclosed system 30 allows the field personnel to identify the equipment 20 that failed/malfunctioned (Block 326) so it can be added for demobilization.

Once the well service is completed, the personnel can check the equipment 20 according to the documented procedures (Block 332), can determine if equipment 20 is to stay at the rig (Decision 334), determine if there were any failures (Decision 336), perform maintenance (Block 338), and the like. Field personnel can directly access the inspection procedures, field maintenance procedures, and other documentation by reading the RFID tags or other machine-readable indica 25 of the pieces of equipment 20 as they are handled and processed.

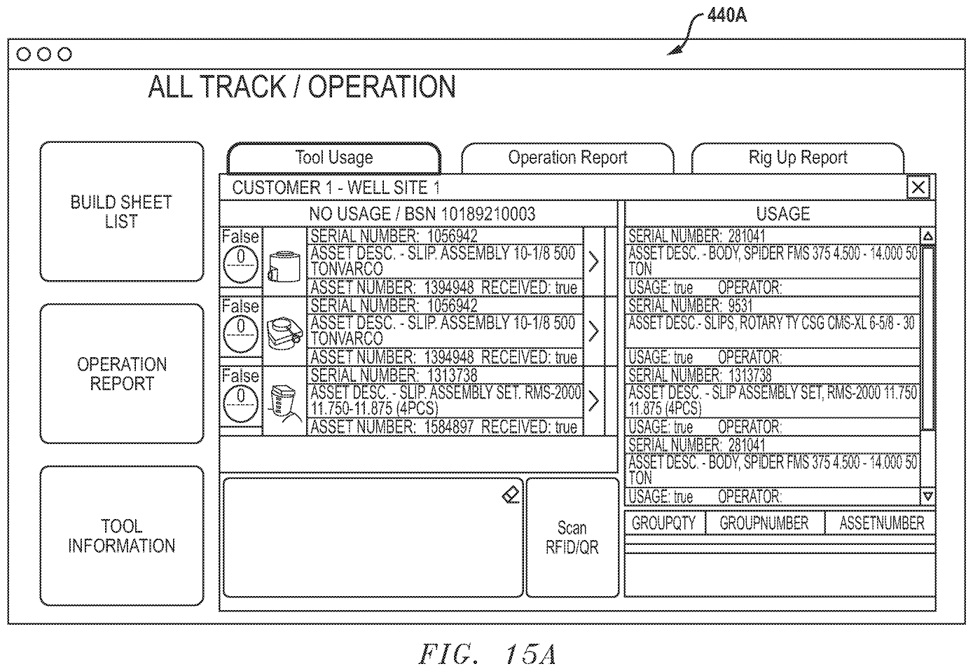

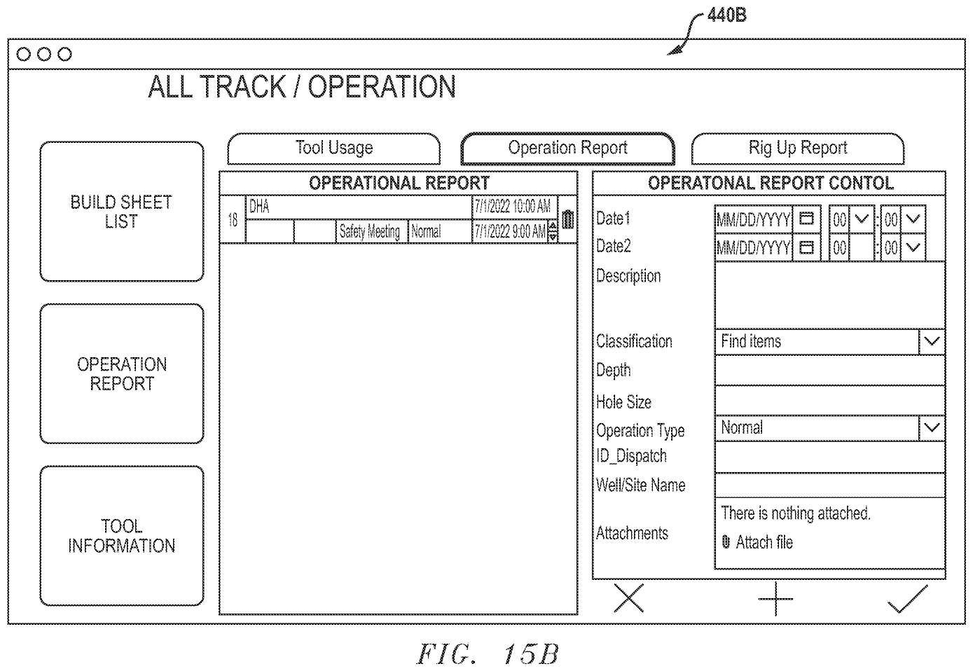

As brief examples, FIG. 15A shows an example user interface 440A having an operation report with tool usage in a well service job for a customer, and FIG. 15B shows an example user interface 440B having an operation report for a well service job for a customer.

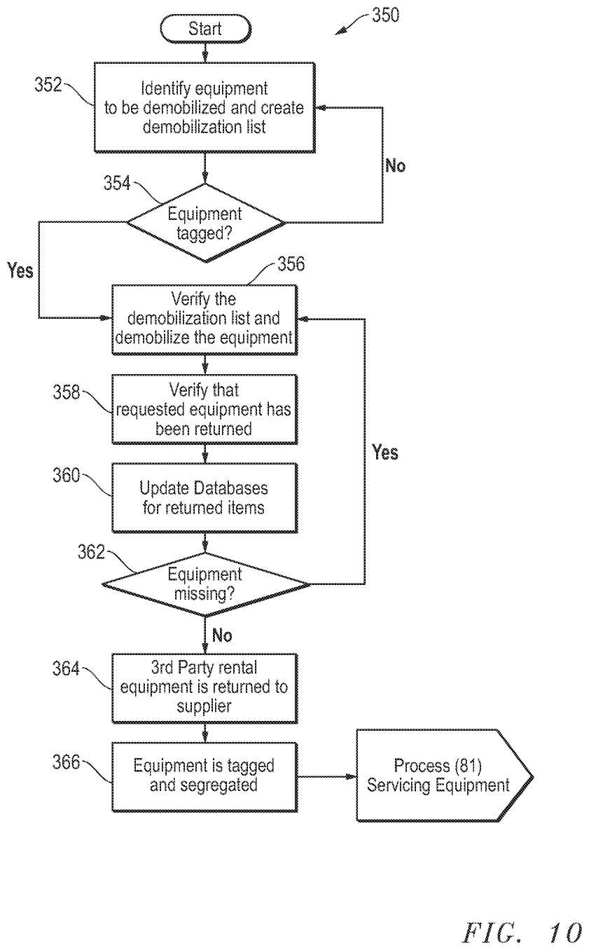

FIG. 10 illustrates a flowchart of a demobilization process 350 of equipment 20 according to the present disclosure. Using the disclosed system 30, field personnel identify equipment 20 to be demobilized and create a demobilization list 66 (Block 352). Some equipment 20 may not be tagged with machine-readable indica 25 (e.g. RFID tag) because the previous indicia 25 were removed or the like. Therefore, such equipment 20 to be demobilized can be verified and retagged with new indicia (Decision 354).

The demobilization list 66 is verified, and the equipment 20 is demobilized from the well site (Block 356). Verifications can be performed by reading the RFID tags or other machine-readable indica 25 of the equipment 20 as it is handled and processed.

At the service provider, personnel can verify that the required equipment 20 has been returned (Block 358), can update the databases accordingly, such as capital asset management systems and the like (Block 360), and can check for missing equipment 20 (Decision 362).

Equipment 20 can be easily sorted and segregated between main, backup, and rental equipment based on the machine-readable indica 25 (RFID tags) and tracking information (Blocks 364, 366). Finally, services of the equipment 20 can be performed and tracked using the RFID tags or other machine-readable indica 25 and tracking information. Testing and inspection can be performed, and performance issues can be reported. Scheduled maintenance can be checked, and service and repairs can be performed. Each of these steps can be facilitated using the user interfaces, the RFID tags or other machine-readable indica 25, the tracking information, and the like of the disclosed system 30.

The techniques of the present disclosure can be implemented in digital electronic circuitry, or in computer hardware, firmware, software, or in combinations of these. Apparatus for practicing the disclosed techniques can be implemented in a computer program product tangibly embodied in a machine-readable storage device for execution by a programmable processor; and method steps of the disclosed techniques can be performed by a programmable processor executing a program of instructions to perform functions of the disclosed techniques by operating on input data and generating output. The disclosed techniques can be implemented advantageously in one or more computer programs that are executable on a programmable system including at least one programmable processor coupled to receive data and instructions from, and to transmit data and instructions to, a data storage system, at least one input device, and at least one output device. Each computer program can be implemented in a high-level procedural or object-oriented programming language, or in assembly or machine language if desired; and in any case, the language can be a compiled or interpreted language. Suitable processors include, by way of example, both general and special purpose microprocessors. Generally, a processor will receive instructions and data from a read-only memory and/or a random-access memory. Generally, a computer will include one or more mass storage devices for storing data files; such devices include magnetic disks, such as internal hard disks and removable disks; magneto-optical disks; and optical disks. Storage devices suitable for tangibly embodying computer program instructions and data include all forms of non-volatile memory, including by way of example semiconductor memory devices, such as EPROM, EEPROM, and flash memory devices; magnetic disks such as internal hard disks and removable disks; magneto-optical disks; and CD-ROM disks. Any of the foregoing can be supplemented by, or incorporated in, ASICs (application-specific integrated circuits).

The foregoing description of preferred and other embodiments is not intended to limit or restrict the scope or applicability of the inventive concepts conceived of by the Applicants. It will be appreciated with the benefit of the present disclosure that features described above in accordance with any embodiment or aspect of the disclosed subject matter can be utilized, either alone or in combination, with any other described feature, in any other embodiment or aspect of the disclosed subject matter.

In exchange for disclosing the inventive concepts contained herein, the Applicants desire all patent rights afforded by the appended claims. Therefore, it is intended that the appended claims include all modifications and alterations to the full extent that they come within the scope of the following claims or the equivalents thereof.

1. A method implemented in a computerized client-server system for monitoring well service equipment used in performing well services at well sites, the method comprising:
coding, in one or more databases of the computerized client-server system, (i) product line codes for each of a plurality of product lines covering the well service equipment, (ii) operational classification codes for each of a plurality of operations in each product line, and (iii) unique identification codes for each of a plurality of the well service equipment in each product line code;
encoding, with the computerized client-server system, machine-readable indicia with coded identifiers for each of the well service equipment, each coded identifier at least including the product line code, the operational classification code, and the unique identification code for the respective well service equipment;
physically associating the encoded machine-readable indicia with the respective well service equipment;
associating, in the one or more databases, tracking information with the coded identifiers for each of the well service equipment;
compiling, at a server side of the computerized client-server system, a design list to implement a given well service using a plurality of given well service equipment at a given well site;
remotely tracking, at the server side of the computerized client-server system, the given well service equipment for the given well service at the given well site using the coded identifiers of the encoded machine-readable indicia by:
dispatching the given well service equipment in the given design list from a dispatch site to the given well site by verifying the encoded machine-readable indicia for the given well service equipment;
obtaining, from a client side of the computerized client-server system, a dispatched list of the encoded machine-readable indicia for the given well service equipment obtained at the given well site to implement the given well service; and
verifying the dispatched list to the design list.

2. The method of claim 1, wherein remotely tracking at the server side further comprises:
obtaining, at the server side from the client side, a demobilized list of the encoded machine-readable indicia obtained at the given well site to demobilize the given well service equipment from the well site; and
verifying the demobilized list to the design list.

3. The method of claim 2, further comprising:
obtaining, at the server side, servicing information of the given demobilized well service equipment; and
associating, in the one or more databases, the obtained servicing information with the tracking information for the given demobilized well service equipment.

4. The method of claim 1, further comprising coding, in the one or more databases, quantity codes for each of the well service equipment having a plurality of associated items, each quantity code identifying a total number of the associated items for the respective well service equipment and identifying a given number of the associated item of the respective well equipment in the total number of items, wherein each of the coded identifiers for each of the well service equipment further include the quantity code.

5. The method of claim 4, further comprising locally tracking, at the client side of the computerized client-server system, the given well service equipment for the given well service at the given well site using the coded identifiers of the encoded machine-readable indicia by:
decoding the coded identifiers from the encoded machine-readable indicia of the given well service equipment;
verifying directly from the quantity codes that the given numbers of the associated items of a respective one of the well service equipment fail to match the total number of the items identified; and
producing a warning in response to the verification.

6. The method of claim 1, further comprising coding, in the one or more databases, inspection codes for each of the well service equipment, each inspection code identifying an inspection date for the respective well service equipment, wherein each of the coded identifiers for each of the well service equipment further include the inspection code.

7. The method of claim 6, further comprising locally tracking, at the client side of the computerized client-server system, the given well service equipment for the given well service at the given well site using the coded identifiers of the encoded machine-readable indicia by:
decoding the coded identifiers from the encoded machine-readable indicia of the given well service equipment;
verifying directly from the inspection codes that the inspection date of a respective one of the given well service equipment fails outside a predefined time period; and
producing a warning in response to the verification.

8. The method of claim 1, further comprising locally tracking, at the client side of the computerized client-server system, the given well service equipment for the given well service at the given well site using the coded identifiers of the encoded machine-readable indicia by:
compiling, at the client side, the dispatched list of the encoded machine-readable indicia for the given well service equipment obtained at the given well site to implement the given well service; and
uploading the dispatched list from the client side to the server side of the computerized client-server system for the verification against the design list

9. The method of claim 8, wherein compiling, at the client side, the dispatched list of the encoded machine-readable indicia comprises locally reading the encoded machine-readable indicia at the client side; and locally storing the coded identifiers at the client side.

10. The method of claim 1, wherein locally tracking, at the client side, the given well service equipment for the given well service further comprises:
compiling, at the client side, a demobilized list of the encoded machine-readable indicia for the given well service equipment for the given well service to demobilize from the given well site; and
uploading the demobilized list from the client side to the server side of the computerized client-server system for verification against the design list.

11. The method of claim 1, wherein the product line codes are associated with one or more of drilling, completions, artificial lift, tubular running services, wireline, cementation products, liner hangers, intervention tools, drilling services, and software; wherein the operational classification codes are associated with one or more of function of equipment, rig up equipment, downhole equipment, surface communication system, rig floor equipment, slips and tubular handling, top drive and elevator, pressure control equipment, radioactive source/HAZMAT, subsurface system, pump system and mud pit, crane and mast operations, ready box/tool box, hydraulic power unit, and auxiliary equipment; and wherein the unique identification codes are associated with capital asset management information.

12. The method of claim 1, wherein physically associating the encoded machine-readable indicia with the respective well service equipment comprises affixing at least one of scannable codes, quick response (QR) codes, bar codes, two-dimensional matrix codes, and radio frequency identification (RFID) devices on the respective well service equipment.

13. The method of claim 1, wherein associating the tracking information with the coded identifiers for each of the well service equipment comprises maintaining one or more of usage information, servicing information, and testing information of the well service equipment.

14. The method of claim 1, wherein compiling, at the server side of the computerized client-server system, the design list to implement the given well service using the given well service equipment at the given well site further comprises providing one or more graphical user interfaces at the server side, the one or more graphical user interfaces being accessible by the client side and including information associated with the design list, the given well service, and the given well service equipment.

15. The method of claim 1, wherein encoding the machine-readable indicia with the coded identifiers comprises encoding at least one of scannable codes, quick response (QR) codes, bar codes, two-dimensional matrix codes, and radio frequency identification (RFID) devices with the coded identifiers.

16. A programmable storage device having program instructions stored thereon for causing a programmable control device to perform a method according to claim 1 implemented in a computerized client-server system of monitoring well service equipment used in performing well services at well sites.

17. A computerized system of a client-server architecture, the computerized system comprising:
a database component storing product line codes for each of a plurality of product lines covering well service equipment, operational classification codes for each of a plurality of operations in each product line, and unique identification codes for each of a plurality of the well service equipment in each product line;
an interface component being configured to communicate with a client side of the client-server architecture; and
a server component in operable communication with the database component and the interface component, the server component being configured to:
encode machine-readable indicia with coded identifiers for each of the well service equipment, each coded identifier at least including the product line code, the operational classification code, and the unique identification code for the respective well service equipment;
associate tracking information with the coded identifiers for each of the well service equipment;
compile a design list to implement a given well service using a plurality of given well service equipment at a given well site;
receive a dispatched list of the given well service equipment obtained at the given well site to implement the given well service; and
verify the dispatched list to the design list to remotely track the given well service equipment for the given well service at the given well site using the coded identifiers of the encoded machine-readable indicia.
